(19) United States
(12) Patent Application Publication
(10) Pub. No.: US 2009/0280614 A1
(43) Pub. Date: Nov. 12, 2009

(54) Method of making a P-type metal-oxide semiconductor transistor and method of making a complementary metal-oxide semiconductor transistor

(76) Inventors: Neng-Kuo Chen, Hsin-Chu City (TW); Chien-Chung Huang, Tai-Chung Hsien (TW); Jei-Ming Chen, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/503,042

(22) Filed: Jul. 14, 2009

Related U.S. Application Data
(63) Continuation of application No. 11/752,940, filed on May 24, 2007.

(51) Int. Cl. H01L 21/336

(52) U.S. Cl. 438/305; 257/E21.437

(57) ABSTRACT

A method is disclosed to make a strained-silicon PMOS or CMOS transistor, in which, a compressive stress film is formed by reacting a silane having at least one substituent selected from the group consisting of hydrocarbyl, hydrocarboxy, carbonyl, formyl, carboxylic group, ester group, and halo group and ammonia, or a conventional compressive stress film is implanted with fluorine atoms, oxygen atoms, or carbon atoms, so as to improve the properties of negative bias temperature instability (NBTI).

### CROSS REFERENCE TO RELATED APPLICATIONS

This application is a continuation of U.S. patent application Ser. No. 11/752,940, filed May 24, 2007, entitled “Method of making a P-type metal-oxide semiconductor transistor and method of making a complementary metal-oxide semiconductor transistor”, the entirety of which is incorporated by reference.

### BACKGROUND OF THE INVENTION

1. Field of the Invention

The present invention relates to a method of making a metal-oxide semiconductor (MOS) transistor, and particularly to a method of making a strained-silicon MOS transistor having alleviated negative bias temperature instability (NBTI).

2. Description of the Prior Art

As the semiconductor processes advance to the deep sub-micron (such as 45 nanometers or less) era, increasing the driving current for MOS transistors by high stress films has become an important topic. Currently, the utilization of high stress films to increase the driving current of MOS transistors is divided into two categories. The first category is to form a poly stressor before the formation of nickel silicides. The second category is to form a contact etch stop layer (CESL) after the formation of the nickel silicides.

In the process of forming the contact etch stop layer, the process temperature should be maintained below 430° C. due to the intolerability to overly high temperatures of the nickel silicides. In the past, the fabrication of the high stress films involved the deposition of a film composed of silicon nitride (SiN), in which the film was utilized to increase the driving current of the MOS transistor.

Please refer to FIG. 1 and FIG. 2. FIG. 1 and FIG. 2 are schematically cross-sectional diagrams showing a conventional technique to form a high compressive stress film on a P-type metal-oxide semiconductor (PMOS) transistor. As shown in FIG. 1, a semiconductor substrate 10, such as a silicon substrate, is provided and a gate structure 12 is formed on the semiconductor substrate 10. The gate structure 12 includes a gate oxide layer 14, a gate 16 disposed on the gate oxide layer 14, a cap layer 18 disposed on the gate 16, and a spacer 20. Generally, the gate oxide layer 14 is composed of silicon dioxide (SiO₂), the gate 16 is composed of doped polysilicon, and the cap layer 18 is composed of silicon nitride to protect the gate 16. Additionally, a shallow trench isolation (STI) 22 is formed around the active area of the gate structure 12 within the semiconductor substrate 10. Thereafter, an ion implantation process is performed to form a source/drain region 26 in the semiconductor substrate 10 around the spacer 20. Next, a metal layer, such as a nickel layer (not shown), is sputtered on the surface of the semiconductor substrate 10 and the gate structure 12, and a rapid thermal annealing (RTA) process is performed to react the metal with the gate 16 and part of the source/drain region 26 and form a metal silicide layer. The un-reacted metal is removed thereafter.

As shown in FIG. 2, a plasma enhanced chemical vapor deposition (PECVD) process is performed in a chamber by injecting silane (SiH₄) and ammonia (NH₃) to form a high compressive stress film 28 on the surface of the gate structure 12 and the source/drain region 26. The high compressive stress film 28 is then utilized to compress the region below the gate 16, that is, the lattice structure in the channel region of the semiconductor substrate 10, thereby increasing the hole mobility in the channel region and the driving current of the strained-silicon PMOS transistor.

However, in the aforesaid conventional method, as the silane-based material is utilized to fabricate the SiN compressive stress film by a PECVD process, a serious deterioration of NBTI tends to occur. As shown in FIG. 3, changes of threshold voltage of MOS transistors on semiconductor wafers with sample batch numbers of 1, 2, and 3 having SiN compressive stress films thereon with compressive stress of −0.2, −2.4, and −2.7 GPa respectively are measured by applying a stress voltage in a measuring time period. When the stress of SiN compressive stress film reaches about −0.2 GPa or above, changes of threshold voltage are more than 80 mV, indicating the deterioration of NBTI.

Therefore, a novel method of making PMOS transistor is still needed to making a strained-silicon PMOS transistor having improved NBTI properties.

### SUMMARY OF THE INVENTION

One object of the present invention is to provide a method of making a PMOS transistor and to provide a technically related method of making a complementary metal-oxide semiconductor (CMOS) transistor, to make a strained-silicon PMOS transistor and a CMOS transistor having improved properties of NBTI.

In one aspect of the present invention, the method of making a PMOS transistor according to the present invention comprises steps as follows. First, a semiconductor substrate is provided. A gate structure and a source/drain region are formed on the semiconductor substrate. Next, a silane (hereinafter also referred to as “substituted silane”) having at least one substituent selected from the group consisting of hydrocarbyl, hydrocarboxy, carbonyl, formyl, carboxylic group, ester group, and halo group is provided, and ammonia is provided, such that the substituted silane is reacted with ammonia to form a compressive stress film on the surface of the gate structure and the source/drain region.

In another aspect of the present invention, the method of making a PMOS transistor according to the present invention comprises steps as follows. First, a semiconductor substrate is provided. A gate structure and a source/drain region are formed on the semiconductor substrate. Next, a compressive stress film is formed on the surface of the gate structure and the source/drain region Finally, the compressive stress film is implanted with fluorine atoms, oxygen atoms, or carbon atoms.

In further another aspect of the present invention, the method of making a CMOS transistor according to the present invention comprises steps as follows. First, a semiconductor substrate is provided. The semiconductor substrate comprises an N-type active area and a P-type active area. Next, a tensile stress film is formed on the surface of the N-type active area. Thereafter, a silane having at least one substituent selected from the group consisting of hydrocarbyl, hydrocarboxy, carbonyl, formyl, carboxylic group, ester group, and halo group is provided, and ammonia is provided, such that the silane is reacted with ammonia to form a compressive stress film on the surface of the semiconductor substrate, the tensile stress film, and the P-type active area. Thereafter, a mask is formed to cover the compressive stress film positioned on the P-type active area. The portion of the compressive stress film not covered by the mask is removed. Finally, the mask is removed, forming a CMOS transistor.

In further another aspect of the present invention, the method of making a CMOS transistor according to the present invention comprises steps as follows. First, a semiconductor substrate is provided. The semiconductor substrate comprises an N-type active area and a P-type active area. Next, a tensile stress film is formed on the surface of the N-type active area. Thereafter, a compressive stress film is formed on the surface of the semiconductor substrate, the tensile stress film, and the P-type active area. The compressive stress film is implanted with fluorine atoms, oxygen atoms, or carbon atoms. Thereafter, a mask is formed to cover the compressive stress film positioned on the P-type active area. The portion of the compressive stress film not covered by the mask is removed. Finally, the mask is removed, forming a CMOS transistor.

In further another aspect of the present invention, the method of making a CMOS transistor according to the present invention comprises steps as follows. First, a semiconductor substrate is provided. The semiconductor substrate comprises an N-type active area and a P-type active area. Next, a silane having at least one substituent selected from the group consisting of hydrocarbyl, hydrocarboxy, carbonyl, formyl, carboxylic group, ester group, and halo group is provided, and ammonia is provided, such that the silane is reacted with ammonia to form a compressive stress film on the surface of the semiconductor substrate, the N-type active area, and the P-type active area. Thereafter, a mask is formed to cover the compressive stress film positioned on the P-type active area. The portion of the compressive stress film not covered by the mask is removed. The mask is removed. Finally, a tensile stress film is formed on the surface of the N-type active area, forming a CMOS transistor.

In further another aspect of the present invention, the method of making a CMOS transistor according to the present invention comprises steps as follows. First, a semiconductor substrate is provided. The semiconductor substrate comprises an N-type active area and a P-type active area. Next, a compressive stress film is formed on the surface of the semiconductor substrate, the N-type active area, and the P-type active area. The compressive stress film is implanted with fluorine atoms, oxygen atoms, or carbon atoms. Thereafter, a mask is formed to cover the compressive stress film positioned on the P-type active area. The portion of the compressive stress film not covered by the mask is removed. The mask is removed. Finally, a tensile stress film is formed on the surface of the N-type active area, forming a CMOS transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematically cross-sectional diagrams showing a conventional technique to form a high compressive stress film on a PMOS transistor;

FIG. 3 is a plotting of compressive stresses vs. changes of threshold voltages of transistors;

FIG. 4 through FIG. 6 are schematically cross-sectional diagrams showing the method of making a PMOS transistor having a high compressive stress film according to the present invention;

FIG. 7 shows a comparison diagram of NBTI between the devices having a high compressive stress film (SiN film) made by the methods according to the present invention and the prior art;

FIG. 8 is a diagram showing the Fourier Transform Infrared Spectroscopy of the high compressive stress film of the present invention;

FIG. 9 shows one embodiment according to another aspect of the present invention;

FIG. 10 through FIG. 15 are cross-sectional diagrams showing another embodiment to make a CMOS having a dual contact etch stop layer (CESL) according to the present invention; and

FIG. 16 shows one embodiment according to further another aspect of the present invention.

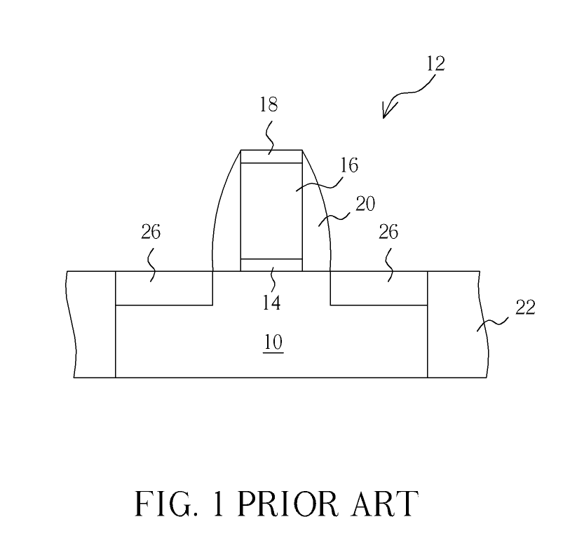

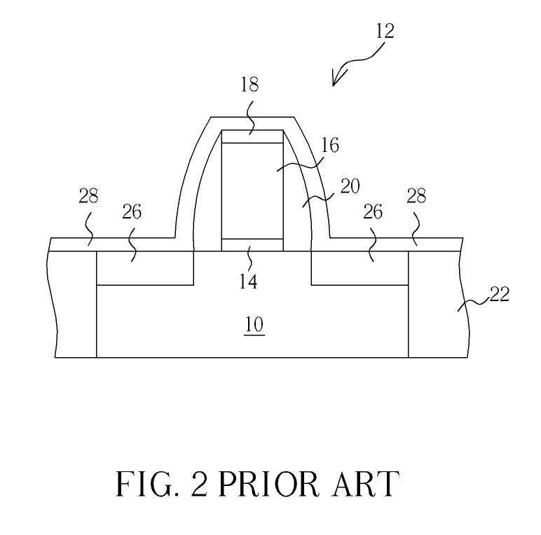

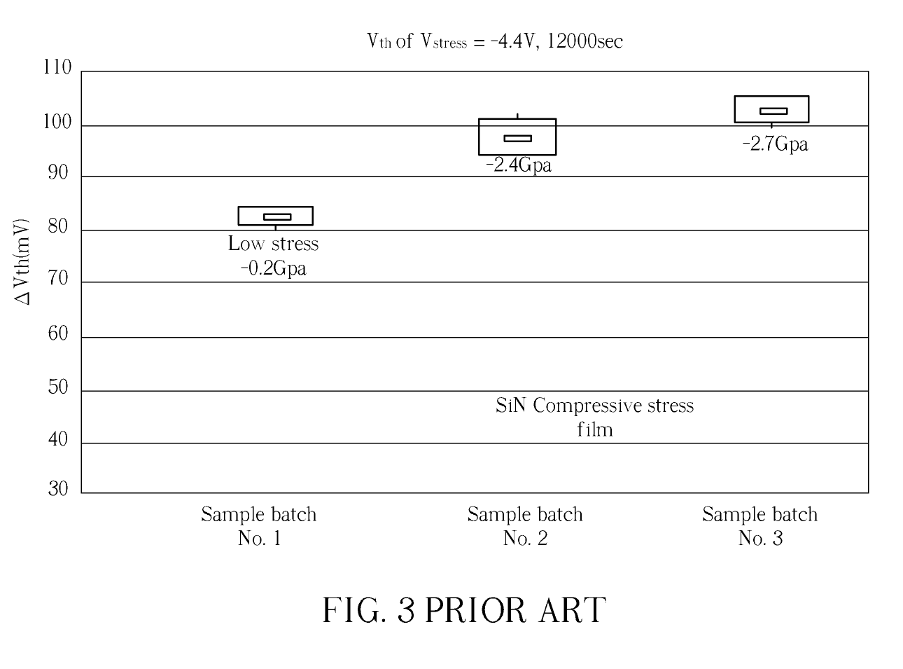

### DETAILED DESCRIPTION

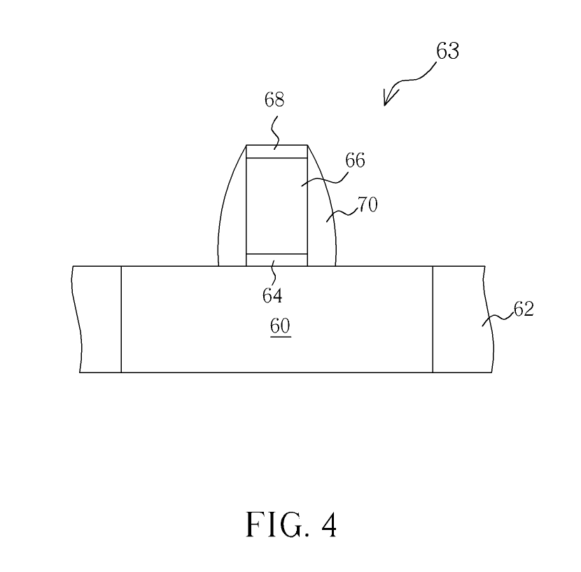

Please refer to FIG. 4 through FIG. 6. FIG. 4 through FIG. 6 are schematically cross-sectional diagrams showing the method of making a PMOS transistor having a high compressive stress film according to the present invention. As shown in FIG. 4, a semiconductor substrate 60, such as a silicon wafer or a silicon on insulator (SOI) substrate, is provided. The semiconductor substrate 60 includes a gate structure 63 thereon. The gate structure 63 generally includes a gate, and may further include, for example, a gate dielectric, a cap layer, a self-alignment metal silicide layer (also referred to as salicide), a liner, or a spacer. As shown in FIG. 4, the gate structure 63 includes a gate 66 and further includes a gate dielectric 64 positioned between the gate 66 and the semiconductor substrate 60, a cap layer 68 disposed on top of the gate 66, and a spacer 70. Preferably, the gate dielectric 64 is composed of insulating materials, such as silicon dioxide or silicon nitride, formed by a thermal oxidation or deposition process, and the cap layer 68 is composed of silicon nitride to protect the gate 66. Additionally, a shallow trench isolation (STI) 62 is formed around the active area (AA) of the gate structure 63 within the semiconductor substrate 60, to insulate the PMOS transistor from other devices.

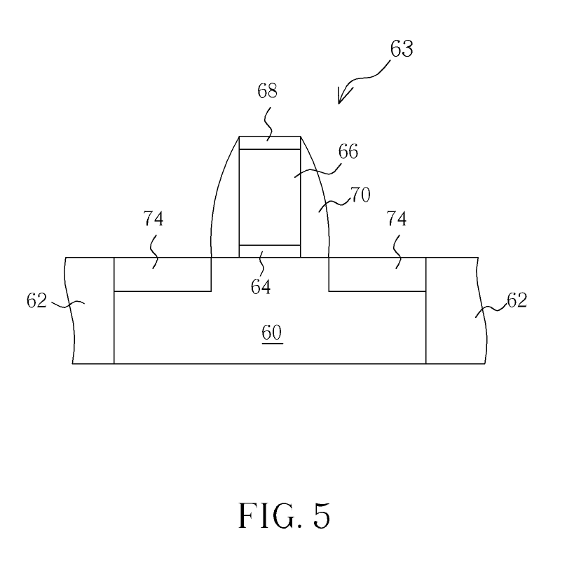

As shown in FIG. 5, an ion implantation process is performed to form a source/drain region 74 around the gate structure 63 and within the semiconductor substrate 60. Next, a rapid thermal annealing process is performed at a high temperature between 900° C. to 1050° C. to activate the dopants in the source/drain region 74 and repair the lattice structure of the semiconductor substrate 60, which has been damaged during the ion implantation process. Additionally, a lightly doped drain (LDD) or a source/drain extension can be formed between the source/drain region 74 and the gate structure 63, or a salicide layer canbe further formedon the surface of the source/drain region 74 and the gate structure 63, depending on the requirement for products or the function of products. It is to be understood that the fabrication of the lightly doped drain, the source/drain extension, and the salicide layer are well known by those of average skill in the art and thus not further explained herein.

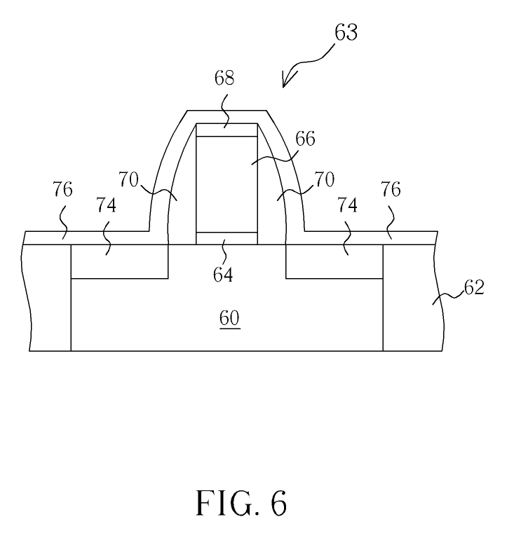

As shown in FIG. 6, a PECVD process is performed to form a high compressive stress film 76 on the gate structure 63 and the source/drain region 74. In a preferred embodiment of the present invention, the PECVD process involves first placing the semiconductor substrate 60 in a reaction chamber, and injecting a silane having at least one substituent selected from the group consisting of hydrocarbyl, hydrocarboxy, carbonyl, formyl, carboxylic group, ester group, and halo group, as a precursor. Next, ammonia is injected into the reaction chamber to react with the substituted silane in the PECVD process to form a high compressive stress film 76 on the surface of the gate structure 63 and the source/drain region 74. Preferably, the flow rate of the precursor being utilized is between 30 grams and 3000 grams per minute, the flow rate of ammonia is between 30 sccm (standard cubic centimeter per minute) and 20000 sccm. Additionally, the powers of a high frequency and low frequency source utilized to form the high compressive stress film 76 may be between 50 watts and 3000 watts, respectively.

The substituted silane used in the present invention may have one or more silicon atoms, such as monosilane, disilane, trisilane, tetrasilane, or pentasilane, having at least one or more substituents. The substituent may be independently selected from the group consisting of hydrocarbyl, hydrocarboxy, carbonyl, formyl, carboxylic group, ester group, and halo group. The hydrocarbyl may be for example an alkyl, alkenyl, or alkynyl. The hydrocarboxy may be represented by —OR, in which, R may be for example alkyl, alkenyl, or alkynyl. The carbonyl may be represented by —COR, in which, R may be for example alkyl, alkenyl, or alkynyl. The formyl is represented by —CHO. The carboxylic group is represented by —COOH. The ester group is represented by —COOR, in which, R may be for example alkyl, alkenyl, or alkynyl. The halo group may be for example fluoro (—F), chloro (—Cl), bromo (—Br), or iodo (—I) group. Preferably, the substituted silane used may be in gas state under the process condition for making the compressive stress film. For example, if the substituted silane may be in gas state or turn into gas state under a low pressure or heating, it may be conveniently used in the present invention.

The method of forming the high compressive stress film using the aforesaid substituted silane as a precursor by PECVD is about equivalent to the method of in-situ doping a high compressive stress film with dopants, such as, oxygen atoms, fluorine atoms, carbon atoms, and the like, such that the H⁺ ions in the film may be trapped and NBTI properties of PMOS may be improved greatly. In addition to the PECVD process, other processes, such as low-pressure chemical vapor deposition (LPCVD) and high-density plasma chemical vapor deposition (HDP CVD), may be used to form high compressive stress films.

Comparisons of performance between the devices having a high compressive stress film (SiN film) made using tetratmethylsilane (also referred to as 4MS herein) as a precursor and using silane-based (SiH₄-based) are listed in Table 1. A high compressive stress film of about −3.6 GPa can be made using tetratmethylsilane as a precursor, and a high compressive stress film of about −3.0 GPa can be made using the unsubstituted silane as a precursor. Both obtain about 53% of PMOS Ion gain.

TABLE 1

| | Process | Device Wafer | | | Blanket Wafer | |
|---|---|---|---|---|---|---|
| | Tem. | Ion | Ion | Ion | Stress | Thick- |
| Film | (° C.) | (μA/μm) | Gain | Gain % | (GPa) | ness (Å) |
| Low stress | 400 | 390.38 | | | −0.2 | |
| standard | | | | | | |
| film | | | | | | |
| SiH₄ −3.0 GPa | 400 | 599.99 | 209.61 | 53.69 | −3.0 | 1013 |
| 4MS −2.7 GPa | 400 | 554.52 | 164.14 | 42.05 | −2.73 | 1011 |
| 4MS −3.0 GPa | 400 | 550.45 | 160.06 | 41.00 | −3.06 | 977 |
| 4MS −3.6 GPa | 480 | 597.89 | 207.51 | 53.16 | −3.55 | 1029 |

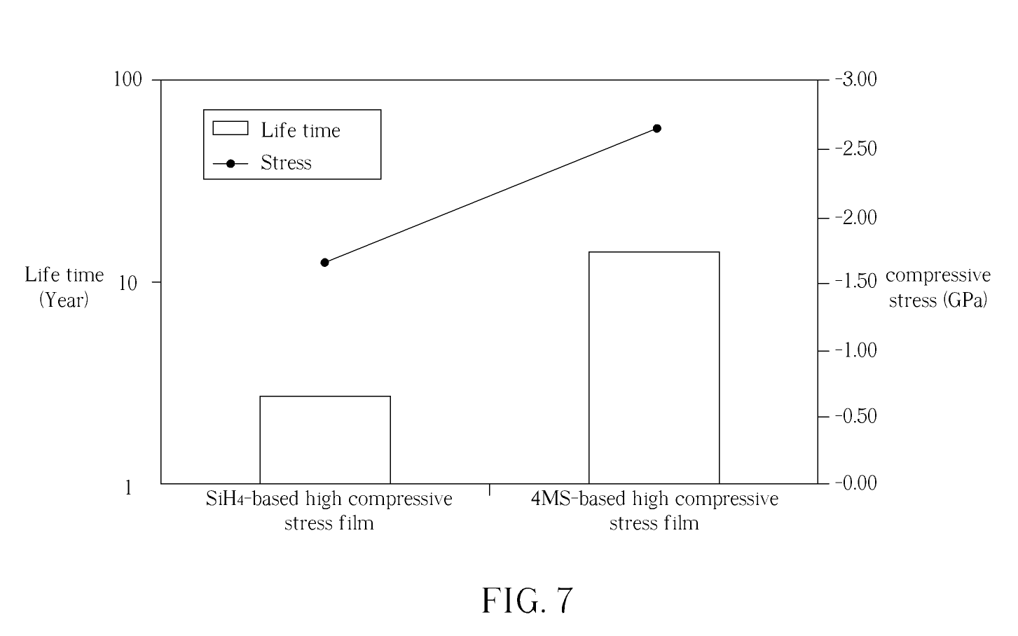

FIG. 7 shows a comparison diagram of NBTI between the devices having a high compressive stress film (SiN film) made using tetramethylsilane and SiH₄, respectively. As shown in FIG. 7, the high compressive stress film made using tetramethylsilane has a stress of −2.75 GPa, and the device having the high compressive stress film made using tetramethylsilane has a lifetime more than 10 years, indicating a good NBTI performance. The high compressive stress film made using SiH₄ has a stress of −0.65 GPa, and the device has a lifetime of about 5 years, indicating an inferior NBTI performance.

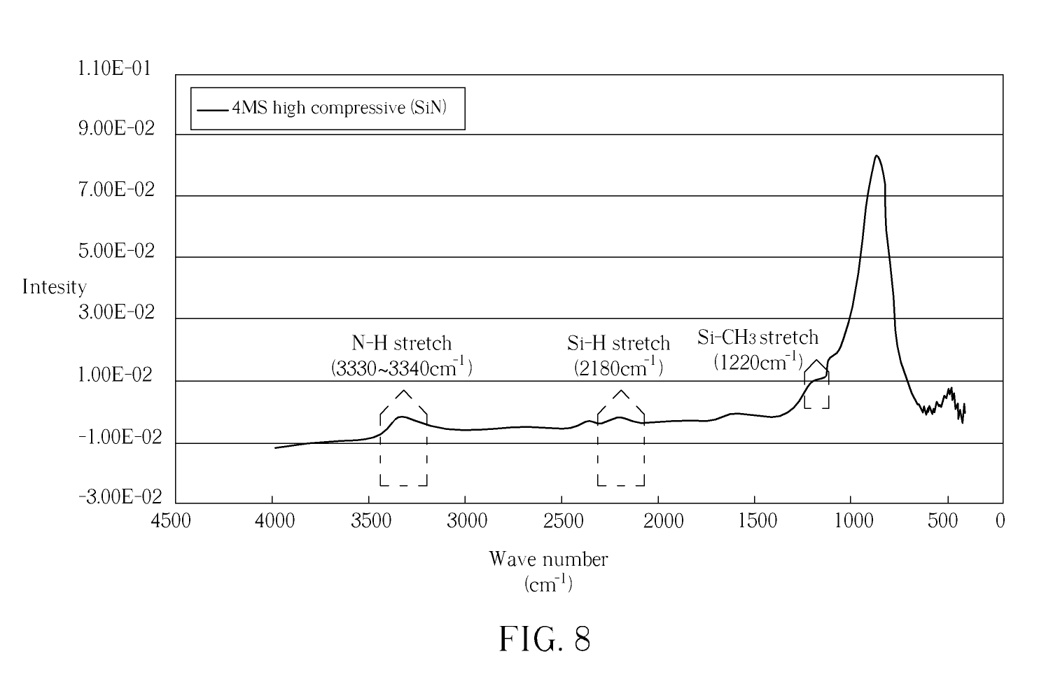

Please refer to FIG. 8. FIG. 8 is a diagram showing the Fourier Transform Infrared (FTIR) Spectroscopy of the high compressive stress film of the present invention. As shown in FIG. 8, the high compressive stress film 76 formed by reacting the tetramethylsilane as a precursor with ammonia in a PECVD process has Si—CH₃ bonds which formed due to the in-situ doping of the high compressive stress film (SiN) with C dopants when the film is being formed. The Si—CH₃ bonds can help to trap H⁺ ions. Accordingly, the NBTI properties of the PMOS can be improved, and, as well as, a high compressive stress film can be made.

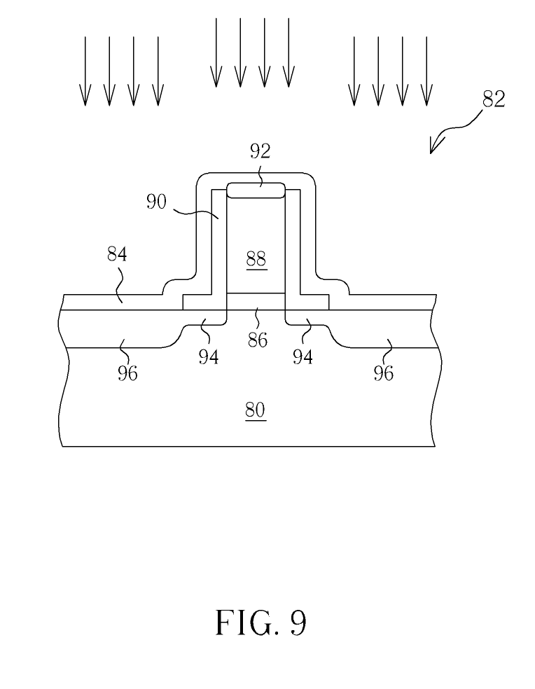

In addition to the method of forming a high compressive stress film using a precursor so as to be equivalent to an in-situ doping with dopants for trapping H⁺ ions, ex-situ doping may be performed, that is, an already-formed high compressive stress film is implanted with fluorine atoms, oxygen atoms, or carbon atoms for trapping H⁺ ions existing in the film. The ability to trap H⁺ ions depends on the electronegativity, and typically, F>O>C. Accordingly, please refer to FIG. 9, showing one embodiment according to another aspect of the present invention. The method of making a PMOS transistor according to the present invention includes steps as follows. First, a semiconductor substrate 80 is provided. Next, a gate structure 82 is formed. The gate structure generally includes a gate and may further include, for example, a gate dielectric, a cap layer, a silicide layer, a liner, or a spacer. As shown in FIG. 9, the gate structure 82 includes a gate 88, and further includes a gate dielectric 86, a liner 90, and a cap layer 92. A source/drain region is formed on the semiconductor substrate. The source/drain region may include a lightly doped drain (LDD) 94 and a heavy doped region 96. A salicide layer may be further formed on the surface of the source/drain region and the gate structure. Thereafter, a compressive stress film 84 is formed on the surface of the gate structure 82 and the source/drain region. The compressive stress film 84 may be formed using siH₄ and ammonia in a PECVD process. Finally, an implantation is performed to implant fluorine atoms, oxygen atoms, or carbon atoms into the compressive stress film 84. The amount of the implants in the film may be for example 10¹² atoms/cm² to 10¹⁷ atoms/cm², and, preferably, 10¹⁴ atoms/cm² to 10¹⁶ atoms/cm². The method for implantation may be for example high current injection (HI), medium current injection (MI), high energy injection (HEI), or the like. The source of fluorine atoms, oxygen atoms, or carbon atoms may be for example fluorine-, oxygen-, or carbon-containing chemicals.

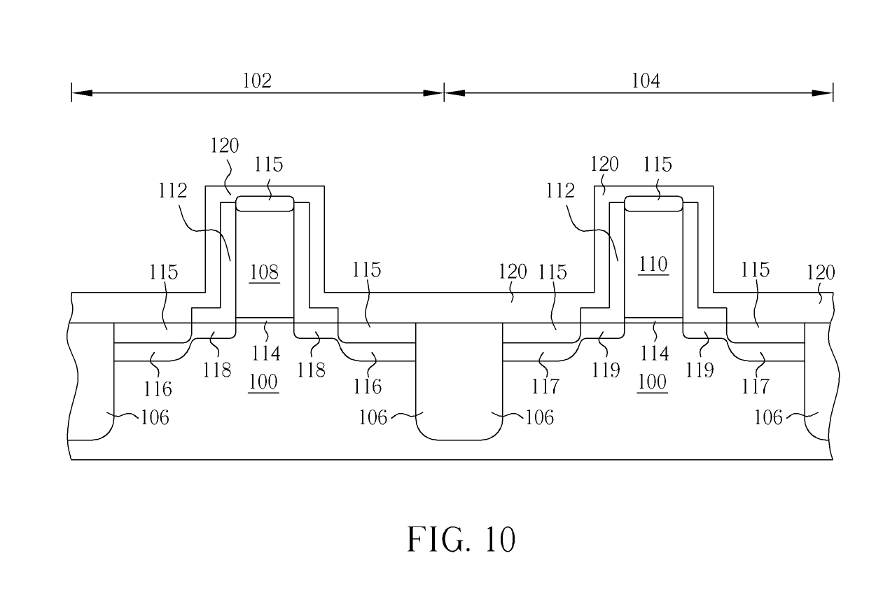

Please refer to FIG. 10 through FIG. 15. FIG. 10 through FIG. 15 are cross-sectional diagrams showing another embodiment to make a CMOS having a dual contact etch stop layer (CESL) according to the present invention. As shown in FIG. 10, a semiconductor substrate 100 having an NMOS region 102 and a PMOS region 104 is provided, in which the NMOS region 102 and the PMOS region 104 are divided by a shallow trench isolation 106. The NMOS region 102 and the PMOS region 104 each include an NMOS gate 108, a PMOS gate 110, and a gate dielectric 114 disposed between the NMOS gate 108, the PMOS gate 110, and the semiconductor substrate 100 respectively. A liner 112 composed of silicon oxide and silicon nitride is formed on the sidewall of the NMOS gate 108 and the PMOS gate 110 thereafter.

Next, an ion implantation process is performed to form a source/drain region 116 around the NMOS gate 108 and a source/drain region 117 around the PMOS gate 110 and within the semiconductor substrate 100. A rapid thermal annealing process is performed thereafter to utilize a high temperature between 900° C. to 1050° C. to activate the dopants within the source/drain regions 116 and 117 and repair the lattice structure of the semiconductor substrate 100, which has been damaged during the ion implantation process. Additionally, lightly doped drains (LDD) 118 and 119 can be formed between the source/drain regions 116, 117 and the gate structures 108, 110, as desired.

Next, a metal layer (not shown), such as a nickel layer, is sputtered on the surface of the semiconductor substrate 100, and a rapid thermal annealing process is performed to react the metal layer with the NMOS gate 108, the PMOS gate 110, and the source/drain regions 116 and 117 to form a plurality of silicide layers 115, to accomplish a salicide process.

After the un-reacted metal layer is removed, a PECVD process is performed to form a high tensile stress film 120 over the surface of the silicide layers 115 within the NMOS region 102 and the PMOS region 104.

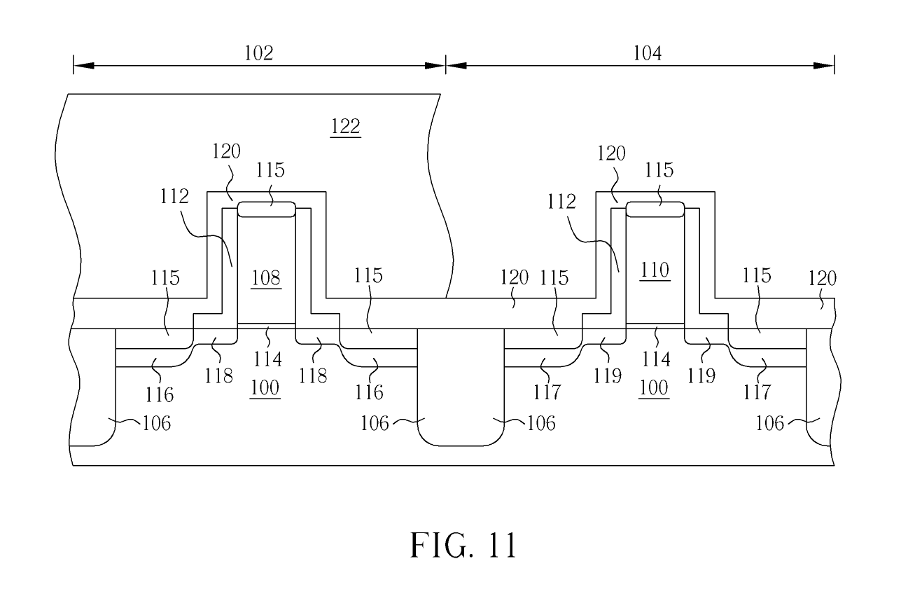

As shown in FIG. 11, a series of coating, exposure, and development processes are performed to form a patterned photoresist 122 on the entire NMOS region 102. Next, an etching process is performed using the patterned photoresist 122 as a mask to remove the high tensile stress film 120 disposed on the PMOS region 104, that is, the portion not covered with the patterned photoresist 122, thereby leaving only the portion of the high tensile stress film 120 on the NMOS gate 108 and the source/drain region 116.

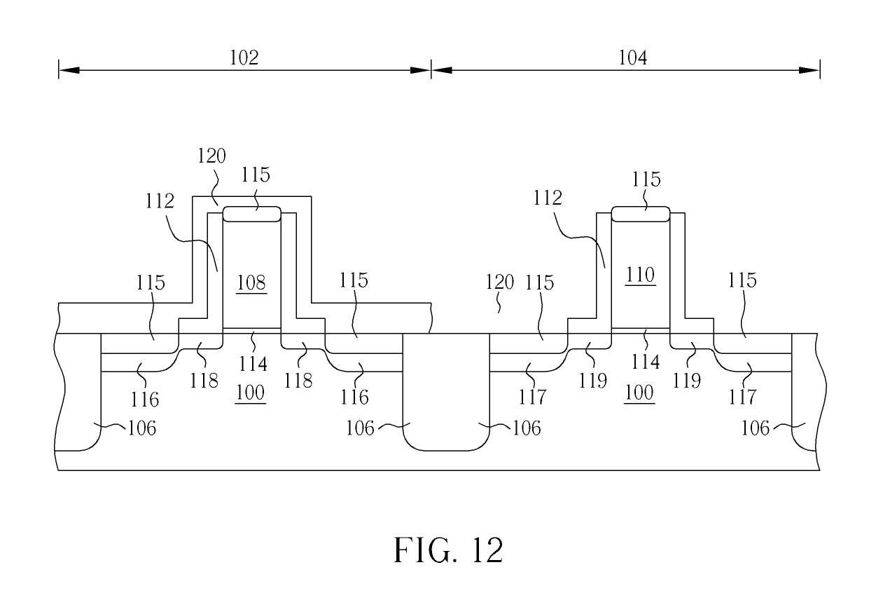

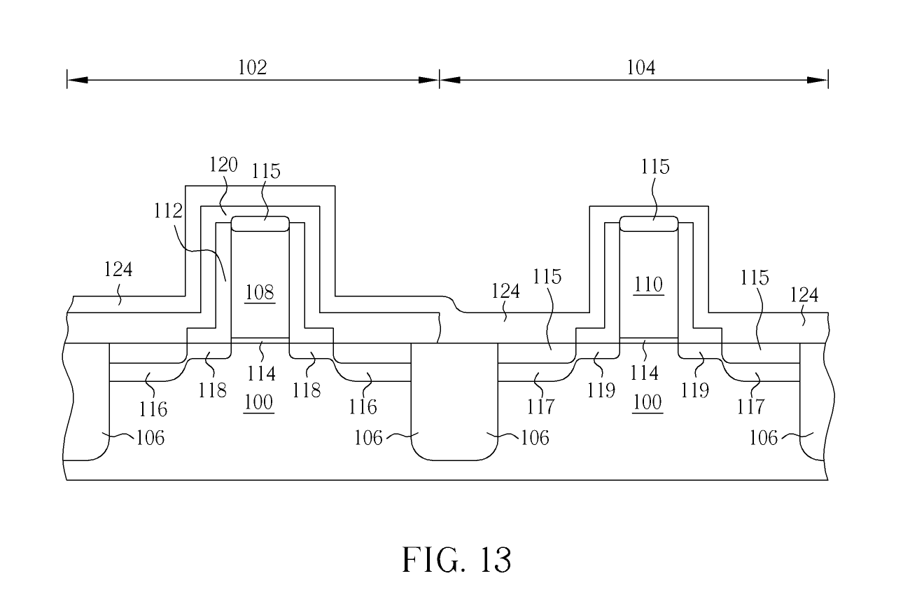

As shown in FIG. 12, the patterned photoresist 122 disposed on the NMOS region 102 is removed thereafter. As shown in FIG. 13, a PECVD process is performed in a reaction chamber (not shown) A substituted silane having at least one substituent selected from the group consisting of hydrocarbyl, hydrocarboxy, carbonyl, formyl, carboxylic group, ester group, and halo group, as a precursor, as mentioned above, is injected into the reaction chamber. Next, ammonia is injected into the reaction chamber to react with the substituted silane, such that the PECVD process is performed to form a high compressive stress film 124 on the NMOS region 102 and the PMOS region 104. Preferably, the flow rate of the precursor being utilized is between 30 and 3000 grams per minute, and the flow rate of ammonia is between 30 sccm and 20000 sccm. Additionally, the powers of a high frequency and a low frequency source utilized to form the high compressive stress film 124 are each between 50 watts and 3000 watts.

As described in the aforementioned embodiments, the high compressive stress film 124 has a bonding of, for example, Si—CH₃, such that the H⁺ ions may be trapped due to the bonding, thereby to improve the NBTI properties of the device.

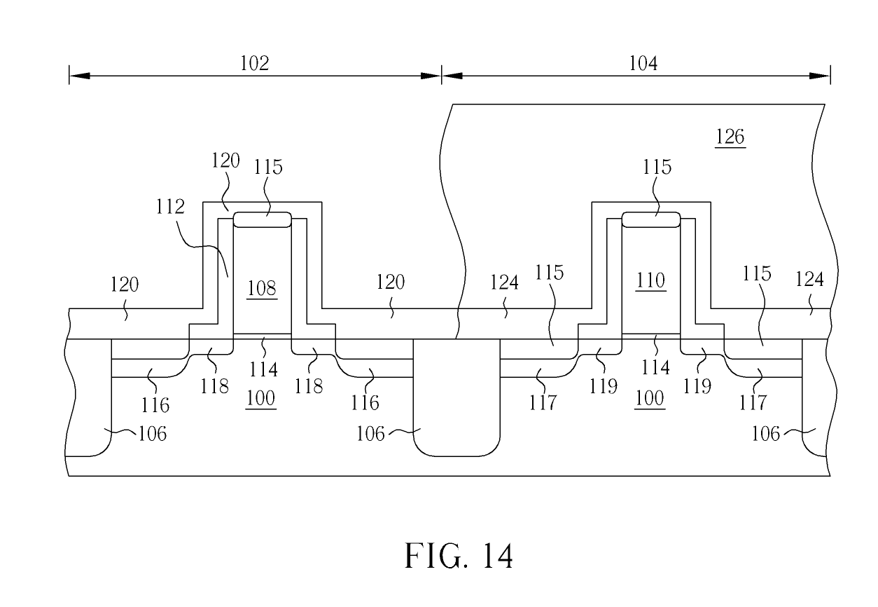

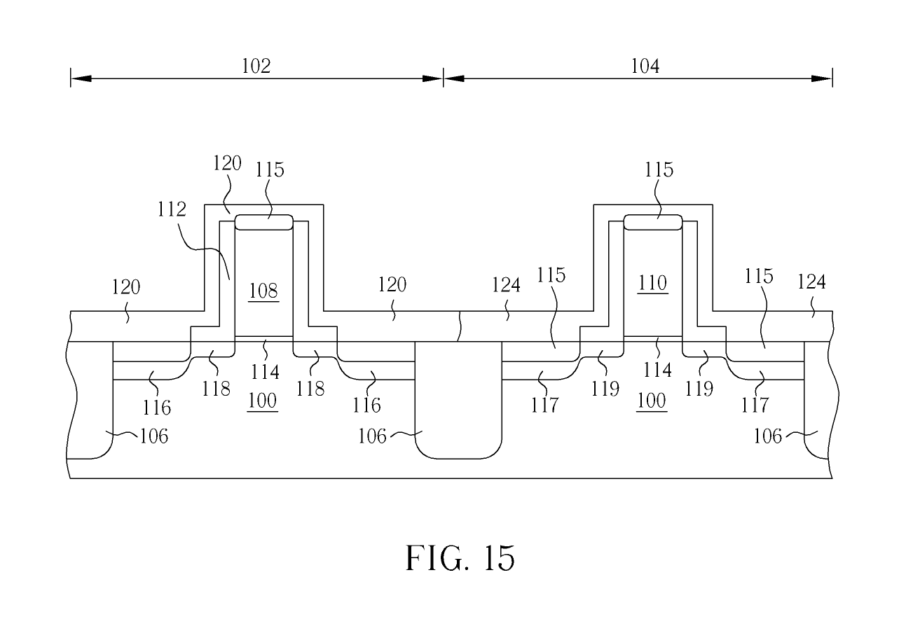

As shown in FIG. 14, a series of coating, exposure, and development processes are performed to form a patterned photoresist 126 on the entire PMOS region 104. Next, an etching process is performed using the patterned photoresist 126 as a mask to remove the high compressive stress film 124 not covered with the patterned photoresist 126, that is, the portion disposed on the NMOS region 102, thereby leaving a high compressive stress film 124 on the surface of the PMOS gate 110 and the source/drain region 117. The patterned photoresist 126 disposed on the PMOS region 104 is removed thereafter, making a CMOS as shown in FIG. 15.

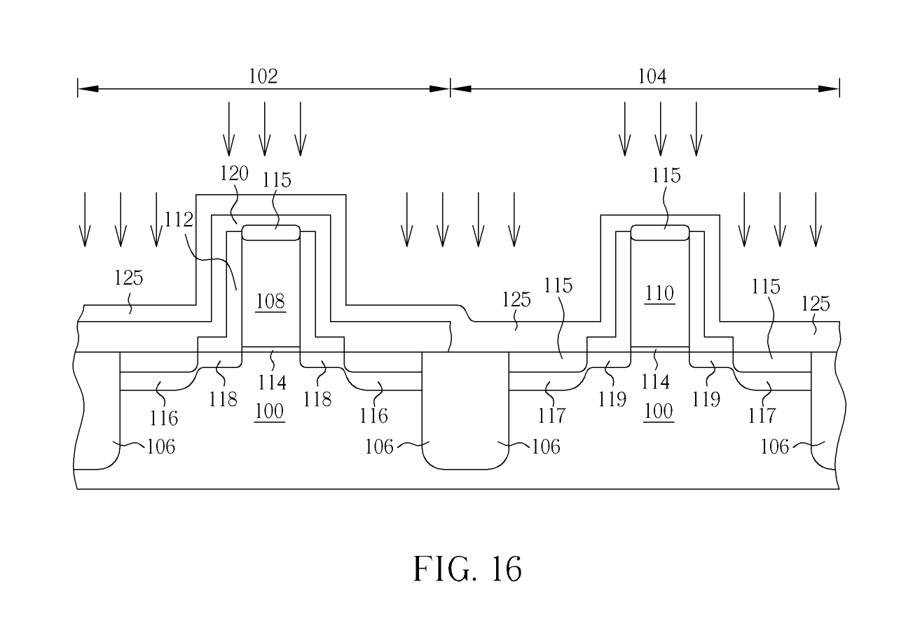

Alternatively, according to another aspect of the present invention, the compressive stress film on the PMOS region of the CMOS in the aforesaid embodiment may be first formed by a conventional method using SiH₄ and ammonia in a PECVD process, and thereafter, the high compressive stress film is implanted with fluorine atoms, oxygen atoms, or carbon atoms to trap H⁺ ions. For example, after the process of making the CMOS is performed till the step as shown in FIG. 12 to form a high tensile stress film 120 on the surface of the NMOS gate 108 and the source/drain region 116, SiH₄ and ammonia are injected into the chamber to perform a PECVD process, forming a high compressive stress film 125 on the NMOS transistor region 102 and the PMOS transistor region 104, as shown in FIG. 16. The flow rate of SiH₄ may be between 30 sccm and 3000 sccm. The flow rate of ammonia may be between 30 sccm and 2000 sccm. The power of a high frequency and low frequency source utilized may be between 50 watts and 3000 watts. Thereafter, an implantation is performed to implant fluorine atoms, oxygen atoms, or carbon atoms into the compressive stress film 125. The amount of the implants in the film may be for example 10¹² atoms/cm² to 10¹⁷ atoms/cm², and preferably, 10¹⁴ atoms/cm² to 10¹⁶ atoms/cm². The method for implantation may be for example high current injection (HI), medium current injection (MI), high energy injection (HEI), or the like. The source of fluorine atoms, oxygen atoms, or carbon atoms may be for example fluorine-, oxygen-, or carbon-containing chemicals. Thereafter, the steps as same as those shown in FIG. 14 are performed to remove the portion of the high compressive stress film 125 covering the NMOS transistor region 102 to leave a high compressive stress film 125 on the gate 110 and the source/drain region 117 of the PMOS region, forming a CMOS as shown in FIG. 15.

Furthermore, the order of forming the high tensile stress film and the high compressive stress film is not limited to the order shown in FIG. 10 through FIG. 15. In the present invention, the high compressive stress film may be formed on the PMOS transistor first, and thereafter, after a corresponding etching process is performed, a high tensile stress film is formed on the NMOS transistor. That is, according to another aspect of the present invention, a semiconductor substrate having an N-type active area and a P-type active area is placed in a reaction chamber. A substituted silane as mentioned above is injected into the chamber as a precursor. Ammonia is injected to react with the substituted silane to form a compressive stress film covering the semiconductor substrate, the N-type active area, and the P-type active area. The substituted silane has at least a substituent selected from the group consisting of hydrocarbyl, hydrocarboxy, carbonyl, formyl, carboxylic group, ester group, and halo group. Thereafter, a mask is formed to cover the compressive stress film on the P-type active area to perform a corresponding etching process to remove the portion of the compressive stress film not covered with the mask. After the mask is removed, a high tensile stress film is formed on the N-type active area and the compressive stress film on the P-type active area. Thereafter, a corresponding etching process is performed to remove the portion of the tensile stress film not covered with the mask, forming a CMOS.

Alternatively, according to further another aspect of the present invention, a high compressive stress film may be first formed on the PMOS transistor, next, a corresponding etching process is performed, and thereafter, a high tensile stress film is formed on the NMOS transistor. The method of forming a high compressive stress film on the PMOS transistor is first to form a typical high compressive stress film, and thereafter to implant fluorine atoms, oxygen atoms, or carbon atoms into the film, such that the high compressive stress film is doped with fluorine atoms, oxygen atoms, or carbon atoms.

In conclusion, in comparison with the PMOS or CMOS having a high compressive stress film made according to the prior art, the high compressive stress film made in the present invention contains dopants such as fluorine atoms, oxygen atoms, or carbon atoms for trapping H⁺ ions which are residues from the process of making the high compressive stress film. The NBTI properties can be accordingly improved and, in turn, the yield and the performance of MOS transistors can be effectively improved.

All combinations and sub-combinations of the above-described features also belong to the present invention. Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of making a P-type metal-oxide-semiconductor transistor, comprising:
providing a semiconductor substrate;
forming a gate structure and a source/drain region on the semiconductor substrate;
forming a compressive stress film on the surface of the gate structure and the source/drain region; and
implanting fluorine atoms, oxygen atoms, or carbon atoms into the compressive stress film.

2. The method of claim 1, wherein the gate structure comprises a gate, a gate dielectric between the gate and the semiconductor substrate, and a cap layer on the gate.

3. The method of claim 1, wherein the gate structure comprises a gate, a gate dielectric between the gate and the semiconductor substrate, a cap layer on the gate, and at least one liner on the sidewall of the gate.

4. The method of claim 1, wherein the gate structure comprises a gate, a gate dielectric between the gate and the semiconductor substrate, a cap layer on the gate, and at least one spacer on the sidewall of the gate.

5. The method of claim 1, wherein the gate structure comprises a gate, a gate dielectric between the gate and the semiconductor substrate, a metal silicide layer on the gate, and at least one liner on the sidewall of the gate.

6. The method of claim 1, wherein the source/drain region comprises a source/drain and a lightly doped drain (LDD).

7. The method of claim 1, wherein the source/drain region further comprises a metal silicide layer on a surface thereof.
